(19) United States
(12) Patent Application Publication
(10) Pub. No.: US 2023/0135911 A1
(43) Pub. Date: May 4, 2023

(54) MOLECULAR BEAM EPITAXY (MBE) REACTORS AND METHODS FOR n+GaN REGROWTH

(71) Applicant: Qorvo US, Inc., Greensboro, NC (US)

(72) Inventors: Edward A. Beam, III, Plano, TX (US); Jinqiao Xie, Allen, TX (US); Antonio Lucero, Garland, TX (US)

(21) Appl. No.: 17/981,041

(22) Filed: Nov. 4, 2022

Related U.S. Application Data
(60) Provisional application No. 63/275,580, filed on Nov. 4, 2021.

(51) Int. Cl. C30B 25/20; C30B 25/16; C30B 29/40

(52) U.S. Cl. CPC C30B 25/20; C30B 25/16; C30B 29/406

(57) ABSTRACT

Molecular beam epitaxy (MBE) reactor structures for the unit process of n+GaN contact regrowth using ammonia as a nitrogen source are provided. Structures and methods for enhancing evacuation of ammonia in a GaN regrowth process are also provided.

### CROSS-REFERENCE TO RELATED APPLICATIONS

This application claims priority benefit of the filing date of U.S. Provisional Patent Application No. 63/275,580, filed on Nov. 4, 2021, the disclosure of which application is herein incorporated by reference in its entirety.

### FIELD OF THE INVENTION

The present invention relates to molecular beam epitaxy (MBE) reactor structures for the unit process of n+GaN contact regrowth using ammonia as a nitrogen source, and more particularly to structures and methods for enhancing evacuation of ammonia in a GaN regrowth process.

### BACKGROUND OF THE INVENTION

Molecular beam epitaxy (MBE) is a technique for thin-film deposition of single crystals in a high-vacuum system. The present disclosure relates to the design of a highly specialized molecular beam epitaxy (MBE) reactor for the unit process of n+GaN contact regrowth, which is needed for reducing the contact resistance of highly scaled, high-frequency gallium nitride (GaN) high electron mobility transistor (HEMT) transistors. The disclosed processes are based on deposition of highly doped GaN material in etched Ohmic contact regions to reduce the contact resistance of the device. The disclosed processes are much more reliable and affordable for manufacturing compared with current general purpose MBE reactors.

Molecular beam epitaxy (MBE) tools have been around for many years, but they are very large and are designed for growing complex epitaxial structures and typically include many types of elemental or gas sources. For a single process, a much simpler tool can be designed. In addition to the size and complexity of common MBE reactors, the use of ammonia (NH₃) as a process gas leads to many issues regarding the reliability of the system and the maintenance requirements that make this process expensive to implement for a high-volume production line. The need for lower contact resistance for high-frequency, highly scaled gallium nitride (GaN) high electron mobility transistor (HEMT) devices that contain wide bandgap barrier layers for high charge density requires that these processes be made practical for manufacturing.

Most of the production-scale MBE reactors in industry were designed for arsenide-based and phosphide-based material systems and were designed for use with evaporated or sublimated source materials. The unreacted arsenide and phosphide materials are very effectively pumped on the liquid nitrogen-filled panels (cryopanels) in the vacuum system, where they condense as solids and remain so when these panels are warmed to room temperature. These MBE reactors were not designed for handling high gas loads, which are characteristic of the plasma nitrogen source required for nitride-based materials. As a result, most MBE reactors that have been used for GaN growth have been modified with higher throughput vacuum pumping systems, but even with these modifications the pumping speed is limited due to the original reactor design. The use of NH₃ for nitride-based material growth is much less common than the plasma-based processes. When NH₃ is introduced into the MBE reactor, the liquid nitrogen-filled cryopanels pump (condense) unreacted NH₃, which freezes as NH₃ (ice) on the surface of the panels, as shown in FIG. 1. Not only is unreacted NH₃ condensed, but the other unreacted source materials condense and are trapped in this ice. Unfortunately, when the cryopanels are warmed up, this ice sublimes as NH₃ gas and the other trapped constituents are released and fall as particles onto the shutters and into the source effusion cells, contaminating them. The liberation of condensed NH₃ also becomes a problem as the thickness of the accumulated ice increases and is radiatively heated by the high temperature substrate heater and gallium silicon, germanium, and other sources in the reactor during normal operation.

Most conventional GaN regrowth reactors and methods use nitrogen-plasma as the source of nitrogen. However, growth of GaN on wafers for use in highly scaled, high-frequency gallium nitride (GaN) high electron mobility transistor (HEMT) transistors require that the GaN growth be selective. Nitrogen-plasma is not as selective as alternative nitrogen sources. The reactors and methods of the present invention use ammonia (NH₃) as a nitrogen source because it is useful for selectivity. However, using ammonia as a nitrogen source has its various challenges. When ammonia is introduced into an MBE reactor, unreacted portions of the ammonia gas build up as ammonia ice on the surface of the cryoshroud within the MBE reactor. Although some of the unreacted ammonia gas is pumped out of the reactor using a pumping system, conventional MBE reactors are not equipped to handle the high gas loads characteristic of nitride-based growth. As a result, conventional MBE reactors are unable to efficiently and effectively evacuate ammonia gas from the reactor during GaN regrowth using these pumping systems, and more ammonia ice is accumulated on the cryoshroud to maintain the pressure during growth.

In order to remove the ammonia ice accumulated on the cryoshroud, a regeneration process is performed to heat the cryoshroud, sublime the ammonia ice, and remove the sublimed ammonia gas from the reactor. Because a substantial amount of ammonia ice accumulates on the cryoshroud rather than being evacuated from the system during conventional methods, there is a significant amount of downtime required to remove the ammonia ice. As such, removal is performed less frequently and the ammonia ice continues to accumulate on the cryoshroud, leading to significant wear and damage to the reactor over time. Further, more contaminants and particles are trapped in the ammonia ice during GaN regrowth. These contaminants and particles may be released and fall during regrowth, regeneration, or both, risking damage to gas injectors positioned at the bottom of the reactor, or other components of the reactor.

Accordingly, there is a need for improved reactors that can enhance evacuation of ammonia gas and avoid accumulation of ice on the cryoshroud during GaN growth. The reactors and methods of the present invention address these and other needs.

Those skilled in the art will appreciate the scope of the present disclosure and realize additional aspects thereof after reading the detailed description included herein in association with the accompanying drawings.

### SUMMARY OF THE INVENTION

Aspects of the invention include molecular beam epitaxy (MBE) reactors for GaN regrowth using ammonia as a nitrogen source, the reactor comprising: a chamber; a wafer port through which a wafer is introduced into the chamber; one or more pump ports; a cryoshroud positioned within the chamber and configured to enhance evacuation of ammonia; and a plurality of gas injectors configured to introduce reactants into the chamber.

In some embodiments, the cryoshroud comprises one or more openings configured to enhance evacuation of ammonia. In some embodiments, the one or more openings comprise a helical geometry. In some embodiments, the cryoshroud comprises a plurality of separate components, and the separate components are configured to enhance evacuation of ammonia. In some embodiments, the plurality of separate components comprise an upper component and a lower component, and the upper and lower components are positioned to form a cylindrical gap between them. In some embodiments, the plurality of separate components are positioned to form one or more vertical gaps between the separate components. In some embodiments, the plurality of separate components are arranged in an interdigitated manner. In some embodiments, the cryoshroud comprises one or more liquid nitrogen-filled cryopanels.

In some embodiments, the wafer port, the one or more pump ports, or any combination thereof are centered on one or more openings in the cryoshroud. In some embodiments, the wafer port is positioned above or below the cryoshroud. In some embodiments, the cryoshroud at least partially overlaps the wafer port, the one or more pump ports, or any combination thereof. In some embodiments, the wafer port, the one or more pump ports, or any combination thereof are not centered on one or more openings in the cryoshroud. In some embodiments, the width of one or more openings in the cryoshroud ranges from 2 inches to 8 inches. In some embodiments, a height of the cryoshroud is less than a height of the chamber. In some embodiments, a height of the cryoshroud is equal to a height of the chamber. In some embodiments, at least one of the one or more openings in the cryoshroud is positioned in a central region of the cryoshroud. In some embodiments, at least one of the one or more openings in the cryoshroud is positioned in a peripheral region of the cryoshroud.

In some embodiments, the plurality of gas injectors enter through a bottom surface of the chamber. In some embodiments, the gas injectors are angled towards the wafer. In some embodiments, at least one of the plurality of gas injectors comprises a distal end, and the distal end is positioned above a bottom level of the cryoshroud. In some embodiments, at least one of the plurality of gas injectors comprises a hydride source and at least one of the plurality of gas injectors comprises a gallium source. In some embodiments, the hydride source is configured to introduce at least one reactant selected from the group consisting of: NH₃, SiH₄, Si₂H₆, GeH₄, and any combination thereof. In some embodiments, the gallium source is configured to introduce at least one reactant selected from the group consisting of: TEGa, TMGa, GaCl₃, and any combination thereof. In some embodiments, at least one of the plurality of gas injectors comprises a distal end, and the reactor further comprises a mechanical shutter configured to cover the distal end of one or more of the gas injectors.

Aspects of the invention include molecular beam epitaxy (MBE) reactors for GaN regrowth using ammonia as a nitrogen source, the reactor comprising: a chamber; a wafer port through which a wafer is introduced into the chamber; one or more pump ports; a cryoshroud positioned within the chamber, the cryoshroud comprising an upper component and a lower component, wherein the lower component is spaced from the upper component by a fixed distance and wherein the spacing of the upper and lower components enhances evacuation of ammonia from the reactor; and a plurality of gas injectors configured to introduce reactants into the chamber.

In some embodiments, the cryoshroud comprises one or more liquid nitrogen-filled cryopanels. In some embodiments, the height of the upper component of the cryoshroud is greater than the height of the lower component of the cryoshroud. In some embodiments, the height of the upper component of the cryoshroud is less than the height of the lower component of the cryoshroud. In some embodiments, the height of the upper component of the cryoshroud is the same as the height of the lower component of the cryoshroud. In some embodiments, the wafer port, the one or more pump ports, or any combination thereof are centered between the upper and lower components of the cryoshroud. In some embodiments, the wafer port, the one or more pump ports, or any combination thereof are not centered between the upper and lower components of the cryoshroud. In some embodiments, the wafer port is positioned above or below the cryoshroud. In some embodiments, the upper component, the lower component, or both at least partially overlap the wafer port, the one or more pump ports, or any combination thereof. In some embodiments, the distance between the upper component and the lower component ranges from 2 inches to 8 inches. In some embodiments, the distance from the bottom edge of the lower component to the top edge of the upper component is less than the height of the chamber. In some embodiments, the distance from the bottom edge of the lower component to the top edge of the upper component is equal to the height of the chamber.

In some embodiments, the plurality of gas injectors enter through a bottom surface of the chamber. In some embodiments, the plurality of gas injectors are angled towards the wafer. In some embodiments, at least one of the plurality of gas injectors comprises a distal end, and the distal end is positioned above a bottom level of the lower component of the cryoshroud. In some embodiments, at least one of the plurality of gas injectors comprises a hydride source and at least one of the plurality of gas injectors comprises a gallium source. In some embodiments, the hydride source is configured to introduce at least one reactant selected from the group consisting of: NH₃, SiH₄, Si₂H₆, GeH₄, and any combination thereof. In some embodiments, the gallium source is configured to introduce at least one reactant selected from the group consisting of: TEGa, TMGa, GaCl₃, and any combination thereof. In some embodiments, at least one of the plurality of gas injectors comprises a distal end, and the reactor further comprises a mechanical shutter configured to cover the distal end of one or more of the gas injectors.

Aspects of the invention include systems for GaN regrowth using ammonia as a nitrogen source, the system comprising: a molecular beam epitaxy (MBE) reactor comprising a chamber, a wafer port through which a wafer is introduced into the chamber, one or more pump ports, a cryoshroud positioned within the chamber and configured to enhance evacuation of ammonia, and a plurality of gas injectors configured to introduce reactants into the chamber; one or more pumps connected to the chamber via the one or more pump ports; and a wafer introducing means configured to introduce the wafer into the chamber through the wafer port.

In some embodiments, the one or more pumps comprise a turbomolecular vacuum pump. In some embodiments, the system further comprises a wafer platform coupled to a shaft positioned through a top surface of the chamber, wherein the wafer platform is configured to accept the wafer from the wafer introducing means. In some embodiments, the wafer platform is positioned above an upper edge of the cryoshroud. In some embodiments, the wafer platform is positioned within one or more openings in the cryoshroud. In some embodiments, at least one of the plurality of gas injectors comprises a distal end, and the reactor further comprises a mechanical shutter configured to cover the distal end of one or more of the gas injectors. In some embodiments, the one or more pumps further comprise a low vacuum, high throughput pump.

In some embodiments, the cryoshroud comprises one or more openings configured to enhance evacuation of ammonia. In some embodiments, the one or more openings comprises a helical geometry. In some embodiments, the cryoshroud comprises a plurality of separate components, and the separate components are configured to enhance evacuation of ammonia. In some embodiments, the plurality of separate components comprises an upper component and a lower component, and the upper and lower components are positioned to form a cylindrical gap between them. In some embodiments, the plurality of separate components are positioned to form one or more vertical gaps between the separate components. In some embodiments, the plurality of separate components are arranged in an interdigitated manner. In some embodiments, the cryoshroud comprises one or more liquid nitrogen-filled cryopanels.

In some embodiments, the wafer port, the one or more pump ports, or any combination thereof are centered on one or more openings in the cryoshroud. In some embodiments, the wafer port is positioned above or below the cryoshroud. In some embodiments, the cryoshroud at least partially overlaps the wafer port, the one or more pump ports, or any combination thereof. In some embodiments, the wafer port, the one or more pump ports, or any combination thereof are not centered on one or more openings in the cryoshroud. In some embodiments, the width of one or more openings in the cryoshroud ranges from 2 inches to 8 inches. In some embodiments, a height of the cryoshroud is less than a height of the chamber. In some embodiments, a height of the cryoshroud is equal to a height of the chamber. In some embodiments, at least one of the one or more openings in the cryoshroud is positioned in a central region of the cryoshroud. In some embodiments, at least one of the one or more openings in the cryoshroud is positioned in a peripheral region of the cryoshroud.

In some embodiments, the plurality of gas injectors enter through a bottom surface of the chamber. In some embodiments, the gas injectors are angled towards the wafer. In some embodiments, at least one of the plurality of gas injectors comprises a distal end, and the distal end is positioned above a bottom level of the cryoshroud. In some embodiments, at least one of the plurality of gas injectors comprises a hydride source and at least one of the plurality of gas injectors comprises a gallium source. In some embodiments, the hydride source is configured to introduce at least one reactant selected from the group consisting of: NH₃, SiH₄, Si₂H₆, GeH₄, and any combination thereof. In some embodiments, the gallium source is configured to introduce at least one reactant selected from the group consisting of: TEGa, TMGa, GaCl₃, and any combination thereof.

Aspects of the invention include methods for GaN regrowth using ammonia gas as a nitrogen source with reduced formation of ammonia ice, the method comprising: cooling a cryoshroud of a molecular beam epitaxy (MBE) reactor; introducing a wafer into the reactor; introducing ammonia gas into the reactor; introducing one or more additional reactants into the reactor configured to react with the ammonia gas on the wafer; reacting at least a portion of the ammonia gas with the one or more additional reactants to facilitate GaN regrowth on the wafer; accumulating a first portion of the unreacted ammonia gas on the cryoshroud as ammonia ice; and evacuating a second portion of the unreacted ammonia gas through one or more openings in the cryoshroud to reduce the accumulation of ammonia ice on the cryoshroud.

In some embodiments, the one or more additional reactants are selected from the group consisting of: SiH₄, Si₂H₆, GeH₄, TEGa, TMGa, and GaCl₃. In some embodiments, evacuating the second portion of the unreacted ammonia gas comprises high throughput vacuum pumping. In some embodiments, accumulating the first portion of the unreacted ammonia gas as ammonia ice further comprises accumulating unreacted portions of the one or more additional reactants within the ammonia ice.

Aspects of the invention include methods for GaN regrowth using ammonia as a nitrogen source with enhanced evacuation of ammonia, the method comprising: cooling a cryoshroud of a molecular beam epitaxy (MBE) reactor; introducing a wafer into the reactor; introducing ammonia gas into the reactor; introducing one or more additional reactants into the reactor configured to react with the ammonia gas on the wafer; reacting at least a portion of the ammonia gas with the one or more additional reactants to facilitate GaN regrowth on the wafer; accumulating a first portion of the unreacted ammonia gas on the cryoshroud as ammonia ice; and evacuating a second portion of the unreacted ammonia gas through one or more openings in the cryoshroud, wherein the one or more openings enhances the evacuation of ammonia from the reactor.

In some embodiments, the one or more additional reactants are selected from the group consisting of: SiH₄, Si₂H₆, GeH₄, TEGa, TMGa, and GaCl₃. In some embodiments, evacuating the second portion of the unreacted ammonia gas comprises high throughput vacuum pumping. In some embodiments, accumulating the first portion of the unreacted ammonia gas as ammonia ice further comprises accumulating unreacted portions of the one or more additional reactants within the ammonia ice.

Aspects of the invention include methods for improving the turnover time of molecular beam epitaxy (MBE) reactors after GaN regrowth processes using ammonia as a nitrogen source, the method comprising: performing a plurality of GaN regrowth unit operations utilizing methods as described herein and forming a reduced thickness of ammonia ice on the cryoshroud; heating the cryoshroud to sublime the ammonia ice accumulated on the cryoshroud thereby forming ammonia gas; and evacuating the sublimed ammonia gas through one or more openings in the cryoshroud; wherein the time required to heat the cryoshroud, sublime the accumulated ammonia ice, and evacuate the sublimed ammonia gas is reduced due to the reduced thickness of ammonia ice on the cryoshroud.

In some embodiments, the improved turnover time for the MBE reactor ranges from 4 to 24 hours. In some embodiments, the improved turnover time for the MBE reactor is less than 4 hours. In some embodiments, the plurality of GaN regrowth unit operations comprises 10 to 20 unit operations. In some embodiments, the plurality of GaN regrowth unit operations comprises 12 unit operations.

These and further aspects will be further explained in the rest of the disclosure.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. In addition, the present disclosure may repeat reference numerals, letters, or both in the various embodiments. This repetition is for the purpose of simplicity and clarity and does not in itself dictate a relationship between the various embodiments and/or configurations discussed.

FIG. 1 is a diagram showing a conventional molecular beam epitaxy (MBE) reactor design.

FIG. 2 is a schematic illustration of a MBE regrowth reactor for GaN regrowth using ammonia as a nitrogen source according to embodiments of the present disclosure.

FIG. 3 is a cross-sectional view of a MBE regrowth reactor in accordance with one or more embodiments.

FIG. 4A is a cross-sectional view of a cryoshroud comprising a helical geometry for use in a MBE reactor in accordance with one or more embodiments.

FIG. 4B is a perspective view of a cryoshroud comprising a helical geometry for use in a MBE reactor in accordance with one or more embodiments.

FIG. 5A is a cross-sectional view of a cryoshroud comprising vertical gaps or openings for use in an MBE reactor in accordance with one or more embodiments.

FIG. 5B is a perspective view of a cryoshroud comprising vertical gaps or openings for use in a MBE reactor in accordance with one or more embodiments.

FIG. 6A is a cross-sectional view of a cryoshroud comprising a plurality of separate components arranged in a horizontal interdigitated manner for use in an MBE reactor in accordance with one or more embodiments.

FIG. 6B is a perspective view of a cryoshroud comprising a plurality of separate components arranged in a horizontal interdigitated manner for use in an MBE reactor in accordance with one or more embodiments.

FIG. 7A is a cross-sectional view of a cryoshroud comprising a plurality of separate components arranged in a vertical interdigitated manner for use in an MBE reactor in accordance with one or more embodiments.

FIG. 7B is a perspective view of a cryoshroud comprising a plurality of separate components arranged in a vertical interdigitated manner for use in an MBE reactor in accordance with one or more embodiments.

FIG. 8 is a system for GaN regrowth using ammonia as a nitrogen source in accordance with one or more embodiments.

FIG. 9 is a flowchart of a process for GaN regrowth using ammonia gas as a nitrogen source with reduced formation of ammonia ice in accordance with one or more embodiments.

FIG. 10 is a flowchart of a process for GaN regrowth using ammonia as a nitrogen source with enhanced evacuation of ammonia in accordance with one or more embodiments.

FIG. 11 is a flowchart of a process for improving the turnover time of an MBE reactor after a GaN regrowth process using ammonia as a nitrogen source in accordance with one or more embodiments.

### DETAILED DESCRIPTION OF THE PREFERRED EMBODIMENTS

Where a range of values is provided, it is understood that each intervening value, to the tenth of the unit of the lower limit unless the context clearly dictates otherwise, between the upper and lower limit of that range and any other stated or intervening value in that stated range is encompassed within the invention. The upper and lower limits of these smaller ranges may independently be included in the smaller ranges is also encompassed within the invention, subject to any specifically excluded limit in the stated range. Where the stated range includes one or both of the limits, ranges excluding either or both of those included limits are also included in the invention.

In the following description, numerous specific details are set forth to provide a more thorough understanding of the present invention. However, it will be apparent to one of skill in the art that the present invention may be practiced without one or more of these specific details. In other instances, well-known features and procedures well known to those skilled in the art have not been described in order to avoid obscuring the invention.

All references cited throughout the disclosure, including patent applications and publications, are incorporated by reference herein in their entirety.

### I. Definitions

By “comprising” it is meant that the recited elements are required in the composition/method/kit, but other elements may be included to form the composition/method/kit etc. within the scope of the claim.

By “consisting essentially of”, it is meant a limitation of the scope of composition or method described to the specified materials or steps that do not materially affect the basic and novel characteristic(s) of the subject invention.

By “consisting of”, it is meant the exclusion from the composition, method, or kit of any element, step, or ingredient not specified in the claim.

By “nitrogen source,” it is meant the reactant or constituent which provides Nitrogen in the reaction for GaN regrowth. In the embodiments described herein, ammonia is used as the nitrogen source.

By “hydride source,” it is meant the reactant or constituent that provides a negative hydrogen ion.

By “gallium source,” it is meant the reactant or constituent that provides Gallium in the reaction for GaN regrowth.

By “cryoshroud,” it is meant a shroud that is cryogenically cooled using, for example, liquid nitrogen. A cryoshroud may be formed from one or more cryopanels.

By arranged in an “interdigitated” manner, it is meant that the separate components of the cryoshroud are arranged in an interlocking manner, such that the finger-like projections on one portion of the cryoshroud interlock with the finger-like projections on a second portion of the cyroshroud.

By “centered on,” it is meant that the center of one element aligns with the center of another element.

By “central region of the cryoshroud,” it is meant plus or minus 20% from the center of the cryoshroud.

By “peripheral region of the cryoshroud,” it is meant more than plus or minus 20% from the center of the cryoshroud. The peripheral region is any region of the cryoshroud outside the central region of the cryoshroud.

By “mechanical shutter,” it is meant a device or mechanism comprising one or more shutter curtains that are capable of covering a component.

By “evacuation,” it is meant removal using, for example, a pumping system.

By “sublime,” it is meant to transform a solid directly into a gas or vapor upon heating without going through the liquid phase.

By “sublimed ammonia gas,” it is meant the ammonia gas resulting from ammonia ice transforming directly into a gas (i.e., subliming) upon heating of the cryoshroud.

By “turnover time,” it is meant the time to regenerate a reactor to remove the ammonia ice formed in the reactor. Specifically, this is the time to heat a cryoshroud in the reactor, sublime the ammonia ice accumulated on the cryoshroud, and evacuate the sublimed ammonia ice.

By “unit operation,” it is meant the operation of a single, GaN regrowth process. For example, a unit operation may be performance of method 900 or method 1000 a single time.

All scientific and technical terms used herein have meanings commonly used in the art unless otherwise specified. The definitions provided herein are to facilitate understanding of certain terms used frequently herein and are not meant to limit the scope of the patent disclosure.

As used here, the singular forms “a,” “an,” and “the” encompass examples having plural referents, unless the content clearly dictates otherwise.

As used here, the term “or” is generally employed in its sense including “and/or” unless the content clearly dictates otherwise. The term “and/or” means one or all of the listed elements or a combination of any two or more of the listed elements.

As used here, “have,” “having,” “include,” “including,” “comprise,” “comprising,” or the like are used in their open-ended sense, and generally mean “including, but not limited to.” It will be understood that “consisting essentially of,” “consisting of,” and the like are subsumed in “comprising” and the like. As used herein, “consisting essentially of,” as it relates to a composition, product, method, or the like, means that the components of the composition, product, method, or the like are limited to the enumerated components and any other components that do not materially affect the basic and novel characteristic(s) of the composition, product, method, or the like.

The words “preferred” and “preferably” refer to examples of the invention that may afford certain benefits, under certain circumstances. However, other examples may also be preferred, under the same or other circumstances. Furthermore, the recitation of one or more preferred examples does not imply that other examples are not useful and is not intended to exclude other examples from the scope of the disclosure, including the claims.

The recitations of numerical ranges by endpoints include all numbers subsumed within that range (e.g., 1 to 5 includes 1, 1.5, 2, 2.75, 3, 3.8, 4, 5, etc. or 10 or less includes 10, 9.4, 7.6, 4.3, 2.9, 1.62, 0.3, etc.). Where a range of values is “up to” a particular value, that value is included within the range.

Any direction referred to here, such as “top,” “bottom,” “left,” “right,” “upper,” “lower,” and other directions and orientations are described herein for clarity in reference to the figures and are not to be limiting of an actual device or system or use of the device or system. Devices or systems as described herein may be used in a number of directions and orientations.

### II. DETAILED DESCRIPTION

The present disclosure provides structures and methods for enhancing evacuation of ammonia in a GaN regrowth process that uses ammonia gas as a nitrogen source. As compared to conventional MBE reactor structures, systems for GaN regrowth, and processes for GaN regrowth, embodiments of the present disclosure enhance evacuation of ammonia gas during GaN regrowth processes, improve the vacuum pumping efficiency of a MBE reactor, reduce the formation of ammonia ice during GaN regrowth processes, reduce turnover time during regeneration of a MBE reactor, reduce contamination and damage of effusion or injector cells, improve the reliability of MBE-related equipment, reduce the overall footprint of systems using MBE reactors for GaN regrowth, and improve manufacturing efficiency of highly scaled, high-frequency gallium nitride (GaN) high electron mobility transistor (HEMT) devices. Due to the formation of ammonia ice in MBE unit operations that employ ammonia gas as a nitrogen source, enhancing the evacuation of ammonia gas from an MBE reactor provides various benefits as described herein.

Examples and embodiments described herein may be used, for example with the methods and devices described in, for example, U.S. Pat. No. 9,865,721 (filed Nov. 17, 2016) to Beam, III et al., entitled “High electron mobility transistor (HEMT) device and method of making the same, which is incorporated by reference herein in its entirety.

Molecular Beam Epitaxy (MBE) Regrowth Reactor

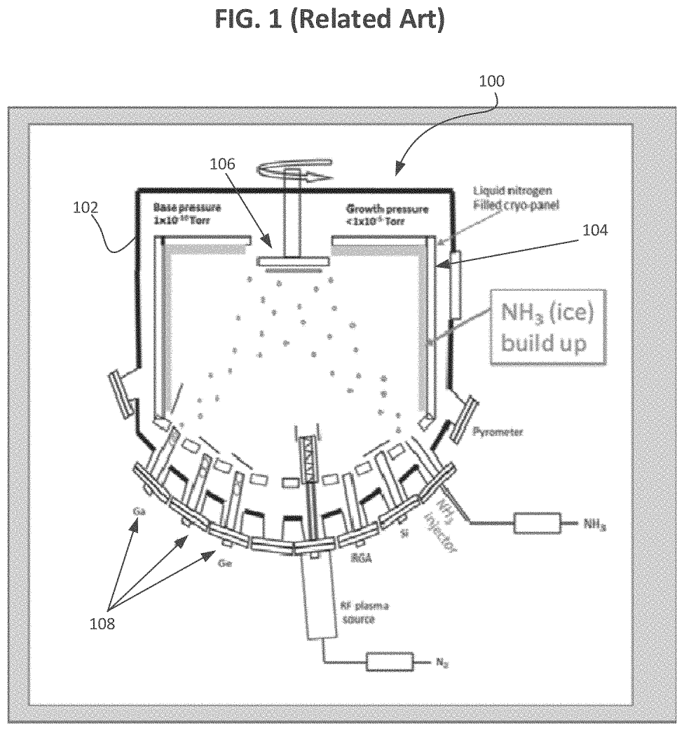

FIG. 1 shows a conventional MBE reactor 100 with a cryoshroud 104 positioned inside a chamber 102 of the MBE reactor 100. The cryoshroud 104 in a conventional MBE reactor 100 contains openings for the wafer holder 106 and the various gas injectors 108. However, the cryoshroud 104 does not include additional gaps beyond what is necessary for exposing various accessories (e.g., gas injectors, effusion cells) to the wafer. The lack of additional gaps in the cryoshroud 104 is to maximize the surface area of the cryoshroud 104 and to facilitate cooling of the cryoshroud 104 and condensation of unreacted source materials on the surface of the cryoshroud 104, such as ammonia ice as depicted in FIG. 1. By condensing unreacted source materials on the cryoshroud 104, the cryoshroud 104 assists pumping systems in maintaining the pressure of the MBE reactor 100 during a GaN regrowth process. However, conventional MBE reactors, like MBE reactor 100 in FIG. 1, were not designed for handling the high gas loads that are characteristic of nitride-based material growth. As a result, most MBE reactors that have been used for GaN growth have been modified with higher throughput vacuum pumping systems, but even with these modifications the pumping speed is limited due to the original reactor design. For example, the cryoshroud in a conventional MBE reactor must bear more of the pumping load considering the inefficiencies of the pumping systems in such conventional MBE reactors. As a result, the cryoshroud 104 of the conventional MBE reactor 100, lacking any additional gaps, facilitates condensation of a substantial amount of unreacted source material, such as ammonia ice, on the surface of the cryoshroud.

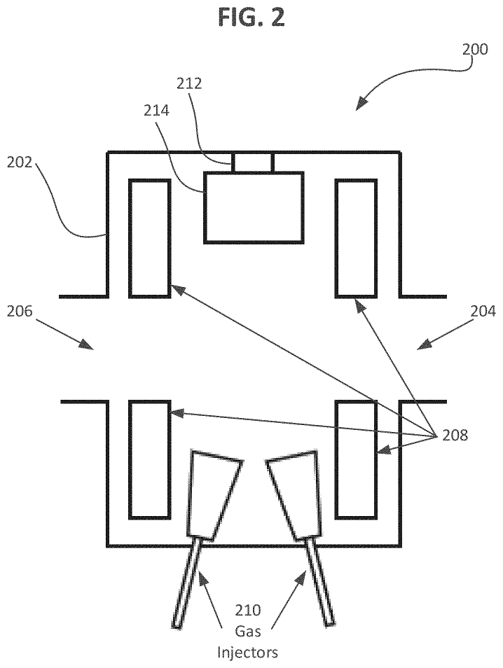

To address the issues presented by conventional MBE reactors as discussed herein, a highly specialized single-function reactor is disclosed that is more suitable for long-term manufacturing. In some embodiments, the MBE reactor of the present invention accommodates 6-inch wafers, may be based on an ammonia nitrogen source for growth selectivity, and may be designed to protect any effusion or injector cells and shutters from particle contamination and damage. FIG. 2 shows a schematic illustration of an MBE regrowth reactor 200 for GaN regrowth using ammonia as a nitrogen source according to embodiments of the present disclosure. The reactor 200 includes a chamber 202. The chamber volume is minimized both to improve the vacuum pumping efficiency and to reduce the overall footprint of the system. The reactor 200 also includes a wafer port 204 through which a wafer may be introduced, and a pump port 206. The pump port 206 is configured to connect one or more pumps to the chamber 202. In some embodiments, high-conductance throughput pumping with turbomolecular vacuum pumps combined with dry roots pumps are used to handle both the gas loads during epitaxial growth and the very high gas loads that occur when the liquid nitrogen (LN₂) cryopanels 208 are warmed up. The reactor also includes a cryoshroud 208 that may include one or more cryopanels as depicted in FIG. 2. The reactor also includes a plurality of gas injectors 210. Gas injectors, which are well within the inner circumference of the cryoshroud as depicted in one embodiment in FIG. 2, are located such that particles falling from the cryopanels do not fall into them. In the vacuum system, particles fall straight down since the pressure is low enough that gas turbulence is avoided. Gas injectors potentially can be used for all growth constituents including Ga, Si, Ge and NH₃. Example sources include silane (SiH₄) or disilane (Si₂H₆) and germanium hydride (GeH₄) diluted in nitrogen or hydrogen for the dopant sources and triethylgallium for the gallium source. Such a total gas source configuration eliminates all high-temperature effusion sources, significantly reducing the heat load within the reactor. As a risk reduction, a single gallium effusion cell may be added with an integrated shutter. This cell can be used if the organometallic gallium source results in too much carbon incorporation in the n+GaN material. Fortunately, gallium evaporates at relatively low temperatures and is one of the easier sources to deal with in an MBE reactor. Finally, a mechanical shutter (not shown) can be designed to move into place above the injector/effusion cell nozzles to further protect the sources during cryoshroud warmups.

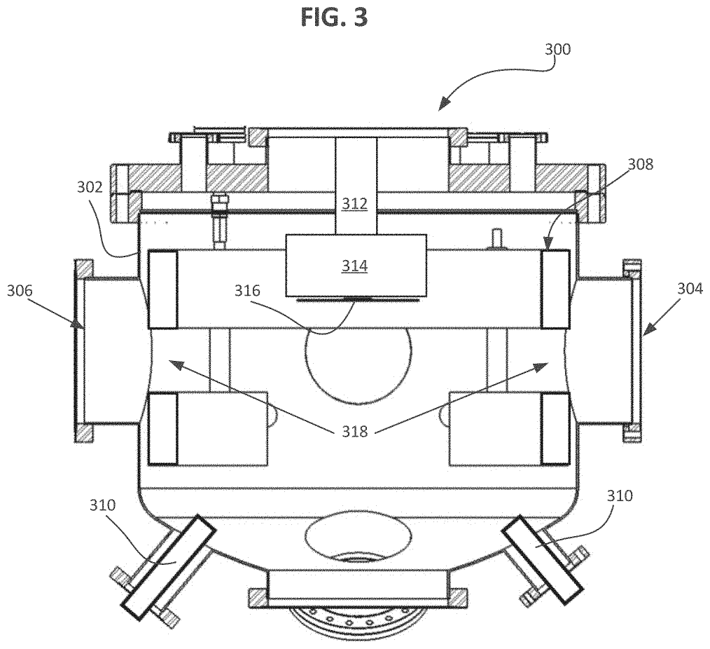

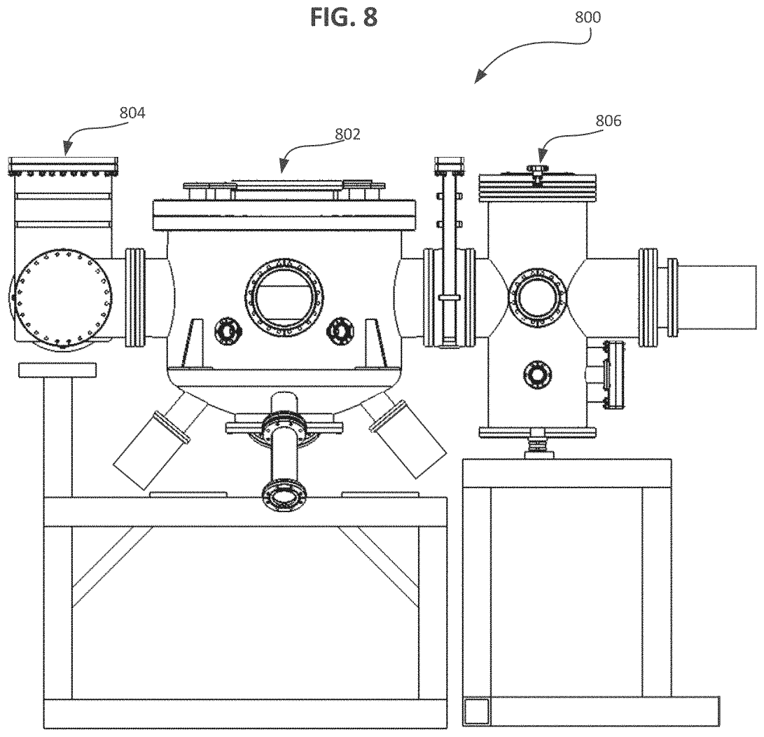

Referring to FIG. 3, depicted is an embodiment of an MBE reactor 300 for GaN regrowth, like the MBE reactor 200 depicted in FIG. 2. In one or more embodiments, the MBE reactor 300 is used for the unit process of n+GaN contact regrowth using ammonia as a nitrogen source. The MBE reactor 300 may be implemented using, for example, system 800 described herein with respect to FIG. 8 or a similar system. The reactor 300 includes a chamber 302. The reactor also includes a wafer port 304. In one or more embodiments, the wafer port is used to introduce a wafer 316 into the chamber 302. The reactor 300 also includes a pump port 306. The wafer port 304 and the pump port 306 are operably connected to the chamber 302. The reactor also includes a cryoshroud 308 positioned within the chamber 302. As depicted in FIG. 3, cryoshroud 308 comprises an upper component and a lower component which are positioned apart from one another to form a gap or opening 318 between them. In the depicted embodiment, the wafer port 304 and the pump port 306 are centered on the gap or opening 318 formed in the cryoshroud 308. The reactor also includes a plurality of gas injectors 310 configured to introduce reactants into the chamber 302 for use in a GaN regrowth process. As depicted in FIG. 3, gas injectors 310 enter through a bottom surface of the chamber 302. In a GaN regrowth process using the reactor 300 according to one or more embodiments, the cryoshroud 308 is cooled using, for example, liquid nitrogen. A wafer 316 is introduced into the chamber 302 of the reactor 300 through the wafer port 304 and further through the gap 318 in the cryoshroud 308. Ammonia gas and one or more additional reactants are introduced into the chamber 302 via the gas injectors 310. To maintain the pressure in the chamber 302 during operation, unreacted portions of the ammonia gas are pumped or evacuated out of the chamber 302 through the gap 318 in the cryoshroud 308 and further through the pump port 306. While some of the unreacted ammonia gas is condensed on the surface of the cryoshroud 308 as ammonia ice, the depicted design of the cryoshroud 308 enhances evacuation of ammonia gas through the gap 318, thereby reducing the formation of ammonia ice on the cryoshroud 308. As a result, the pumping efficiency of the reactor 300 is improved due to the gap 318 in the cryoshroud 308. Methods of using the reactor depicted in FIG. 3 are described further herein.

Wafer port 304 is operably connected to chamber 302 to facilitate introduction of wafer 316 into the reactor 300, and removal of wafer 316 after completion of a GaN regrowth unit operation. The wafer port 304 may be connected to a device or mechanism configured to introduce wafer 316 into the chamber. For example, in some embodiments the wafer port is connected to a load chamber. Further aspects of MBE regrowth systems including means for wafer introduction are discussed further herein. In some embodiments, the wafer port 304 is positioned on one or more gaps 318 in the cryoshroud 308. More specifically, in some embodiments, as depicted in the embodiment of FIG. 3, wafer port 304 is centered on one or more gaps 318 in the cryoshroud 308. In other embodiments, the wafer port 304 is positioned above the cryoshroud 308; in other embodiments, the wafer port 304 is positioned below the cryoshroud 308. In one or more embodiments, the cryoshroud 308 may partially overlap the wafer port 304. For example, as shown in FIG. 3, the upper component and the lower component of the cryoshroud 308 both partially overlap the wafer port 304. In one or more embodiments where the cryoshroud 308 comprises separate components, such as the upper and lower components of cryoshroud 308 depicted in FIG. 3, one or more of the separate components may partially overlap the wafer port 304. As depicted in FIG. 2, in one or more embodiments, the cryoshroud 208 does not overlap the wafer port 204.

Pump port 306 is operably connected to chamber 302 to facilitate evacuation of unreacted constituents, such as unreacted ammonia gas, out of the reactor 300 during a GaN regrowth process. In some embodiments, the reactor 300 includes a plurality of pump ports 306. The pump port 306 may be connected to one or more pumps configured to pump unreacted ammonia gas out of the reactor 300. Further aspects of MBE regrowth systems including one or more pumps are discussed further herein. In one or more embodiments, the pump port 306 is positioned on one or more gaps 318 in the cryoshroud 308. In some embodiments, as depicted in the embodiment in FIG. 3, the pump port 306 is centered on one or more gaps 318 in the cryoshroud 308. Preferably, the pump port 306 is centered on the gap 318 in the cryoshroud 308 to maximize the pump throughput during a GaN regrowth process. In one or more embodiments, the cryoshroud 308 may partially overlap the pump port 306. For example, as shown in FIG. 3, the upper component and the lower component of the cryoshroud 308 both partially overlap the pump port 306. In one or more embodiments where the cryoshroud 308 comprises separate components, such as the upper and lower components of cryoshroud 308 depicted in FIG. 3, one or more of the separate components may partially overlap the pump port 306. As depicted in FIG. 2, in one or more embodiments, the cryoshroud 208 does not overlap the pump port 206.

The positions of the wafer port 304 and the pump port 306 on either side of the reactor 300 as depicted in FIGS. 2 and 3 are not intended to be limiting. One of ordinary skill in the art will readily appreciate that various changes and modifications in the wafer port 304 and the pump port 306 can be made without departing from the spirit or scope of the invention.

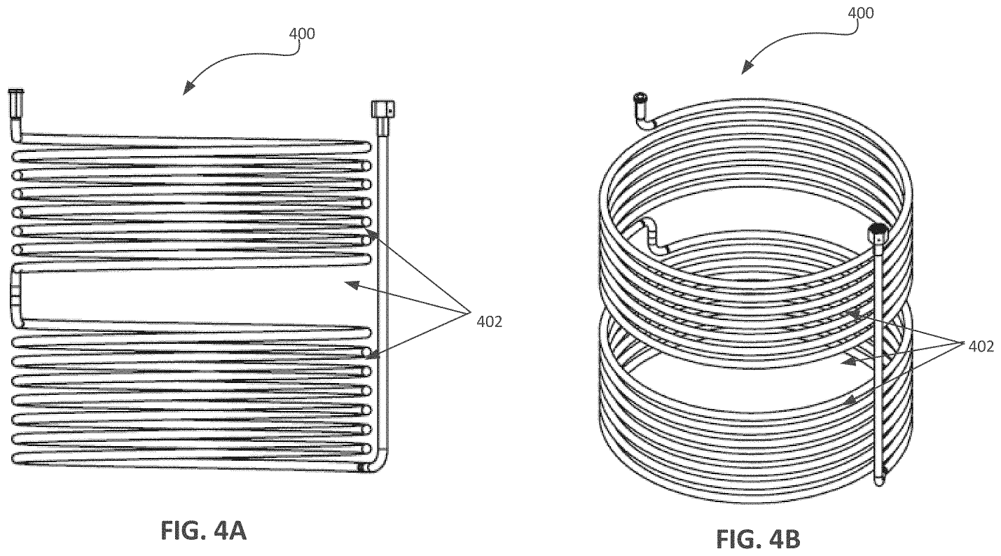

CRYOSHROUDS. Cryoshrouds in accordance with embodiments of the invention can include one or more cryopanels which function to cool the cryoshroud 308 and provide a surface on which unreacted materials may condense in order to maintain the pressure in the reactor 300. In some embodiments, the cryoshroud may include liquid-nitrogen filled cryopanels, such that the cryoshroud 308 includes tubes connected to a liquid nitrogen source for cooling the cryoshroud 308. Cooling of the cryoshroud 308 facilitates condensation of a portion of unreacted ammonia gas on the cryoshroud 308 during a GaN regrowth process using the reactor 300. The cryoshroud 308 also facilitates evacuation of ammonia during the GaN regrowth process using ammonia as a nitrogen source by allowing unreacted ammonia gas to escape the reactor 300. This is accomplished by one or more gaps or openings 318 formed in the cryoshroud 308 in accordance with one or more embodiments of the invention. Compared to cryoshroud 104 of conventional MBE reactors 100, as depicted in FIG. 1, which do not include additional gaps or openings beyond what is necessary for exposing various accessories (e.g., gas injectors, effusion cells) to the wafer in an effort to maximize the surface area of the cryoshroud, the cryoshroud 308 of reactor 300 enhances the evacuation of ammonia as a result of the gaps 318 through which unreacted ammonia gas is pumped out of the reactor chamber 302 during operation. As a result, less unreacted ammonia accumulates on the cryoshroud 308 as ammonia ice, which provides additional benefits as described herein. FIGS. 4A-7B show alternative designs of the cryoshroud 308 in accordance with one or more embodiments.

In one or more embodiments, the cryoshroud 308 may be a single structure with one or more openings 318 to facilitate evacuation of ammonia. In some embodiments, as depicted in FIGS. 4A and 4B, the cryoshroud 400 includes one or more openings 402 with a helical geometry. For example, the cryoshroud 400 may be formed from a helix, coil, or similar structure with a plurality of turns spaced apart by a distance, also referred to as the pitch of the helix. The separation between turns in the cryoshroud 400 having a helical geometry defines the one or more openings 402 and facilitates evacuation of ammonia through the one or more openings 402. In some embodiments, a larger gap 402 may be formed between turns of the cryoshroud having a helical geometry to facilitate introduction and retrieval of wafer 316 in the chamber 302 via the wafer port 304.

In one or more embodiments, the cryoshroud 308 may be formed from a plurality of separate components. In some embodiments, as depicted in FIG. 3, cryoshroud 308 comprises an upper component and a lower component which are positioned to form a gap or opening 318 between them. The gap or opening 318 may be, for example, a cylindrical gap. The lower component may be spaced from the upper component by a fixed distance which ranges from 2 inches to 8 inches in one or more embodiments. For example, in some embodiments, the distance between the upper and lower components may be 2, 3, 4, 5, 6, 7, or 8 inches. Preferably, in some embodiments the distance between the upper and lower components of the cryoshroud 308 is in the range of 3 to 6 inches, such as 4 or 5 inches. The spacing between separate components of the cryoshroud 308 forms one or more gaps or openings 318 in the cryoshroud 308 that enhance evacuation of ammonia from the reactor 300. In some embodiments the height of the upper component is greater than the height of the lower component; in other embodiments, the height of the upper component is less the height of the lower component; in other embodiments, as depicted in FIG. 3, the height of the upper component is equal to the height of the lower component.

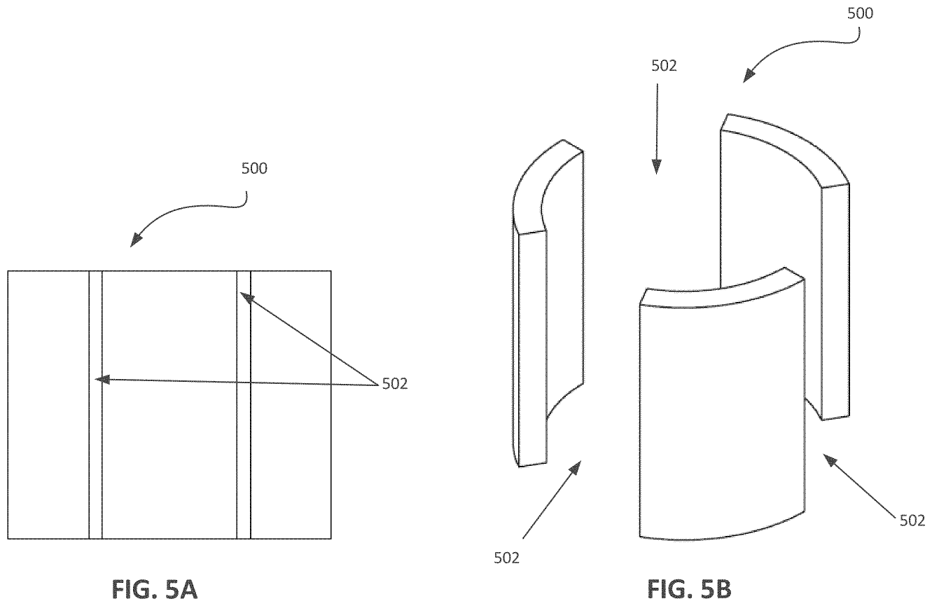

In one or more embodiments, as depicted in FIGS. 5A and 5B, the cryoshroud 500 includes one or more vertical gaps 502 in the cryoshroud 500. The cryoshroud may be a single structure with one or more vertical gaps 502 in some embodiments, or in other embodiments the cryoshroud 500 may be formed from a plurality of separate components positioned to form one or more vertical gaps 502 in between the separate components. The cryoshroud 500 depicted in FIGS. 5A and 5B includes three separate components with three vertical gaps 502 between the separate components. In some embodiments, the cryoshroud 500 includes two separate components with two vertical gaps 502 between the separate components. In other embodiments, the cryoshroud 500 includes four or more separate components positioned to form a plurality of vertical gaps 502 in between the separate components. The vertical gaps 502 in the cryoshroud 500 facilitate evacuation of unreacted ammonia gas through the vertical gaps 502. In some embodiments, one or more of the vertical gaps 502 is positioned to coincide with the wafer port 304 to facilitate introduction and retrieval of wafer 316 in the chamber 302 via the wafer port 304.

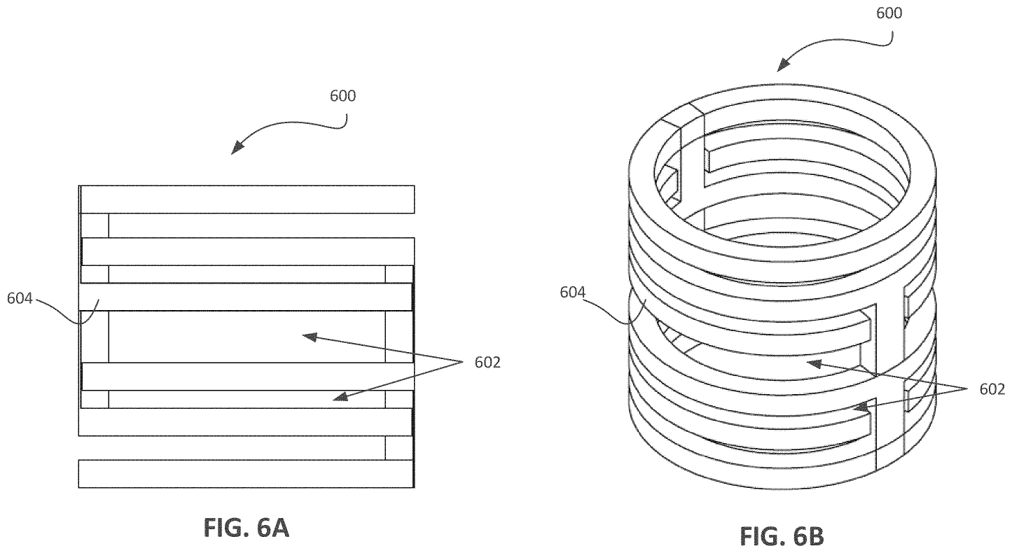

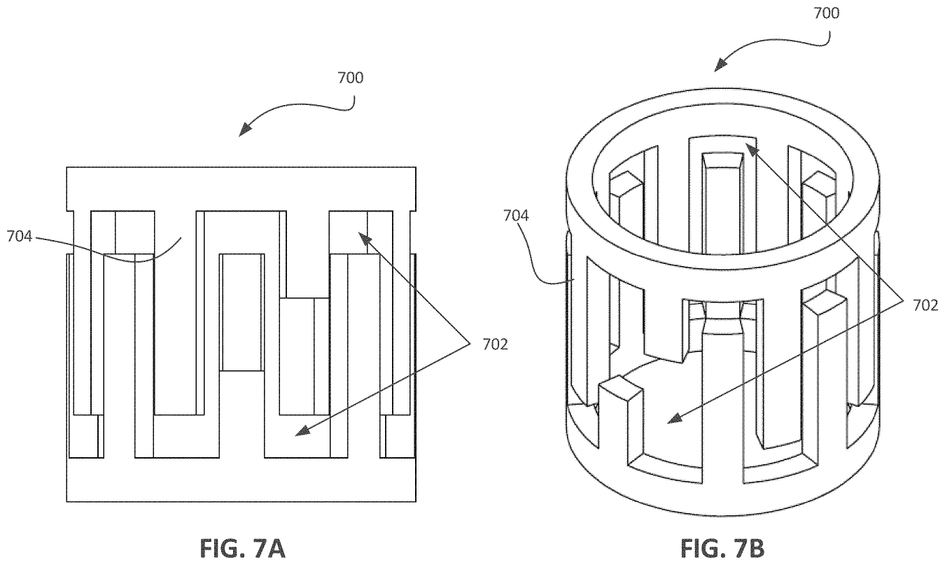

In one or more embodiments, as depicted in FIGS. 6A, 6B, 7A, and 7B, the cryoshroud 600, 700 may include a plurality of separate components arranged in an interdigitated, or interlocking, manner to form horizontal, vertical, or a combination of horizontal and vertical gaps 602, 702 in the cryoshroud 600, 700. In some embodiments, as shown by the cryoshroud 600 in FIGS. 6A and 6B, the separate components are arranged in a horizontal interdigitated manner to form one or more gaps 602 in the cryoshroud. In other embodiments, as shown by the cryoshroud 700 in FIGS. 7A and 7B, the separate components are arranged in a vertical interdigitated manner to form one or more gaps 702 in the cryoshroud. To facilitate introduction and retrieval of wafer 316 in the chamber 302 via wafer port 304, a larger gap 602, 702 may be formed in between one or more of the digits 604, 704 in the interdigitated cryoshroud 600, 700. One of ordinary skill in the art will appreciate that various modifications could be made to the measurements of digits 604, 704, cryoshroud 600, 700, or one or more of gaps 602, 702 to form a larger gap suitable for introduction of wafer 316. For example, the height of two of the digits 704 in FIGS. 7A and 7B are shorter than the heights of the remaining digits 704 to form a larger gap 702 through which wafer 316 may be introduced and retrieved.

With continuing reference to FIG. 3, the height of the cryoshroud 308 extends from a bottom edge of the cryoshroud 308 to the top edge of the cryoshroud 308, including any intervening gaps or openings 318. In some embodiments the height of the cryoshroud 308 is less than the height of the chamber 302, as depicted in FIG. 3. In other embodiments, the height of the cryoshroud 308 is equal to the height of the chamber 302.

In one or more embodiments, the width of the gaps or openings 318 formed in the cryoshroud 308 ranges from 2 inches to 8 inches, such as 2, 3, 4, 5, 6, 7, or 8 inches. Preferably, in some embodiments, the width of the openings 318 ranges from 3 inches to 6 inches, such as 4 or 5 inches.

The gaps or openings 318 may be positioned in various regions of the cryoshroud 308 to enhance evacuation of ammonia. In some embodiments, the gaps or openings 318 are positioned in a central region of the cryoshroud 308, where the central region is defined as plus or minus 20% from the center of the cryoshroud 308. In other embodiments, the gaps or openings 318 are positioned in a peripheral region of the cryoshroud 308, where the peripheral region is defined as more than plus or minus 20% from the center of the cryoshroud 308. Further, in other embodiments of the cryoshroud 308 comprising one or more gaps or openings 318, some of the gaps or openings 318 may be positioned in the central region of the cryoshroud 308, and some of the gaps or openings 318 may be positioned in the peripheral region of the cryoshroud 308. In some embodiments, one or more of the gaps or openings 318 can be positioned such that it occupies both a central region of the cryoshroud and a peripheral region of the cryoshroud (i.e., the opening extends from a central region of the cryoshroud into a peripheral region of the cryoshroud).

GAS INJECTORS. Gas injectors in accordance with the embodiments of the invention can include a plurality of gas injectors which are configured to introduce reactants into the chamber 302 to be used for GaN regrowth. In one or more embodiments, at least one of the gas injectors 310 comprises a hydride source and at least one of the gas injectors comprises a gallium source. In some embodiments, the hydride source introduces ammonia (NH₃) used for GaN regrowth. In some embodiments, the hydride source introduces one or more additional reactants to be used as a dopant in the regrowth process, as described, for example, in U.S. Pat. No. 9,865,721 (filed Nov. 17, 2016) to Beam, III et al., entitled “High electron mobility transistor (HEMT) device and method of making the same”, the disclosure of which is incorporated by reference herein in its entirety.

Examples of additional hydride source reactants include, but are not limited to, NH₃, SiH₄, Si₂H₆, and GeH₄. In some embodiments, the gallium source introduces one or more reactants used for GaN regrowth. Examples of gallium source reactants include, but are not limited to, TEGa, TMGa, and GaCl₃.

In one or more embodiments, the gas injectors 310 are angled towards the wafer 316. In this way, the reactants are introduced into the chamber 302 in a direction towards the wafer 316 to prevent the reactants from interacting with other components in the reactor 300, such as the cryoshroud 308, and to prevent the reactants from reacting with each other prior to reaching the surface of the wafer 316. Once the reactants reach the surface of the wafer 316, at least a portion of the reactants react to facilitate GaN regrowth. In some embodiments, the gas injectors 310 enter through a bottom surface of the chamber. Further, in some embodiments, as depicted in FIG. 2, the gas injectors 210 include a distal end positioned above a bottom level of the cryoshroud 208, where the distal end is the end through which reactants are released and introduced into the reactor 200. When the injectors 210 are positioned in this way, they are protected from particles or contaminants falling from the cryoshroud 208, such as unreacted materials trapped in the ammonia ice that accumulates on the cryoshroud 308 during the regrowth process. In other embodiments, the reactor 300 also includes a mechanical shutter (not shown) that is used to cover the gas injectors 310 from falling particle or contaminants. In use, the mechanical shutter moves above one or more of the gas injectors 310 when they are not operating, such as during a regeneration process as described herein, and shields the injectors 310 from particle contamination or damage.

Systems for GaN Regrowth

Referring to FIG. 8, depicted is a system 800 for GaN regrowth using ammonia as a nitrogen source in accordance with one or more embodiments. System 800 includes an MBE reactor 802. The MBE reactor 802 may be any MBE reactor according to embodiments of the present invention described herein. For example, MBE reactor 300 as described herein with respect to FIG. 3 may be implemented in system 800 as reactor 802. System 800 also includes one or more pumps 804. With reference to FIG. 8, and continuing reference to FIG. 3, pumps 804 are connected to reactor 802 via one or more pump ports 306. System 800 also includes a wafer introducing means 806, such as a wafer load chamber 806 as depicted in FIG. 8, which is connected to reactor 802 via wafer port 304. In some embodiments, system 800 also includes a wafer platform 214, 314 as shown in FIGS. 2 and 3, coupled to a shaft 212, 312, which is configured to accept the wafer from the wafer introducing means 806. In some embodiments, wafer platform 214, 314 includes a heater (not shown) to heat the wafer 316 in preparation for GaN regrowth on the surface of the wafer 316.

PUMPS. Pumps 804 in accordance with embodiments of the invention function to pump unreacted ammonia gas, and in some embodiments, one or more other unreacted materials out of the reactor 802 during performance of the methods as described herein. High gas loads are characteristic of nitride-based material growth processes such as the regrowth of GaN using ammonia according to the embodiments of the present invention. By pumping ammonia gas out of the reactor 802, pumps 804 help maintain the pressure in the reactor 802 during the regrowth process. Similarly, pumps 804 pump unreacted ammonia gas that sublimes as a result of heating the cryoshroud during a regeneration process to melt the ammonia ice as described further herein. In some embodiments, a single pump 804 is used; in other embodiments, more than one pump 804 is used. One of ordinary skill will readily appreciate that any of a variety of suitable pumps can be used in connection with the systems and methods described herein. In some embodiments, pump 804 is a turbomolecular vacuum pump. In some embodiments, pumps 804 may include an additional pump, such as a low vacuum, high throughput pump. In use, these MBE reactor systems typically involve two-stage pumping systems in which a primary pump, e.g., a turbomolecular vacuum pump, is backed by a low vacuum, high throughput backing pump. One non-limiting example of a backing pump is a dry roots pump.

WAFER INTRODUCTION. Wafer introducing means 806 in accordance with embodiments of the invention include a device or mechanism configured to introduce a wafer ready for GaN regrowth into the reactor 802. In some embodiments, the wafer introducing means 806 is capable of heating the wafer 316 to prepare it for GaN regrowth on the surface of the wafer 316. Once the wafer 316 is ready for GaN regrowth, the wafer introducing means 806 introduces the wafer 316 through the wafer port 304 and further through one or more openings 318 in the cryoshroud 308 in some embodiments. In other embodiments, the wafer introducing means 806 introduces the wafer 316 above the cryoshroud 308; in other embodiments, the wafer introducing means 806 introduces the wafer 316 below the cryoshroud 308. In some embodiments where system 800 includes wafer platform 214, 314 coupled to shaft 212, 312, the wafer introducing means 806 introduces the wafer 316 to wafer platform 214, 314 where the wafer 316 is positioned for GaN regrowth. One of ordinary skill will readily appreciate that any of a variety of suitable wafer introducing means can be used in connection with the systems and methods described herein. In some embodiments, the wafer introducing means may be a wafer load chamber 806, as depicted in FIG. 8.

It will be appreciated that MBE reactors as described herein may be much smaller and simpler than conventional MBE reactors used for growing complex epitaxial structures. Rather, MBE reactor 802 (and similarly reactors 200 and 300 depicted in FIGS. 2 and 3), are designed for a single, unit process of n+GaN contact regrowth. Thus, in contrast to conventional MBE reactors, reactor 802 may be designed with a smaller chamber volume and less reactant sources (i.e., less gas injectors). Minimizing the volume of the chamber, such as those depicted in FIGS. 2 and 3 with reference numerals 202 and 302, also improves the pumping efficiency of the system 800. In some embodiments, the footprint of the system 800 ranges from about 28 to about 40 square feet, such as about 30, 32, 34, 36, or 38 square feet. For example, in some embodiments, the footprint of system 800 is estimated at about 32 square feet. Table 1 compares the current state-of-the-art MBE reactor system with the expected performance of this custom single-function system 800 according to the present disclosure.

TABLE 1
N+ Regrowth Reactor Systems

| | | Disclosed |
|---|---|---|
| | | single-function |
| Parameter | Riber 49* | reactor |
| Footprint | 140 sq. ft. | 32 sq. ft. |
| Reactor cost | >$2M | ~$500K |
| Capacity | 16-inch wafer/run | 16-inch wafer/run |
| Wafer handling | Semi-automatic or | Semi-automatic or |
| | fully automatic | fully automatic |
| | wafer transfer | wafer transfer |
| Sources | 10 source ports | 1 to 3 source ports |
| Maintenance time (a.u.) | 10 | 2 |
| Maintenance cost (a.u.) | 10 | 1 |
| Throughput (6-in. | ~24 | ~24 |
| wafers/day) | | |

*Representative of the current state-of-the-art tools in use for GaN epitaxy.

Methods

Various method and systems embodiments described herein enable enhanced evacuation of ammonia gas during GaN regrowth processes. Due to the formation of ammonia ice in MBE unit operations that employ ammonia gas as a nitrogen source, enhancing the evacuation of ammonia gas from an MBE reactor provides various benefits, including, reduced formation of ammonia ice during GaN regrowth processes, reduced turnover time during regeneration of MBE reactors, among others as described herein.

GaN Regrowth Using Ammonia Gas.

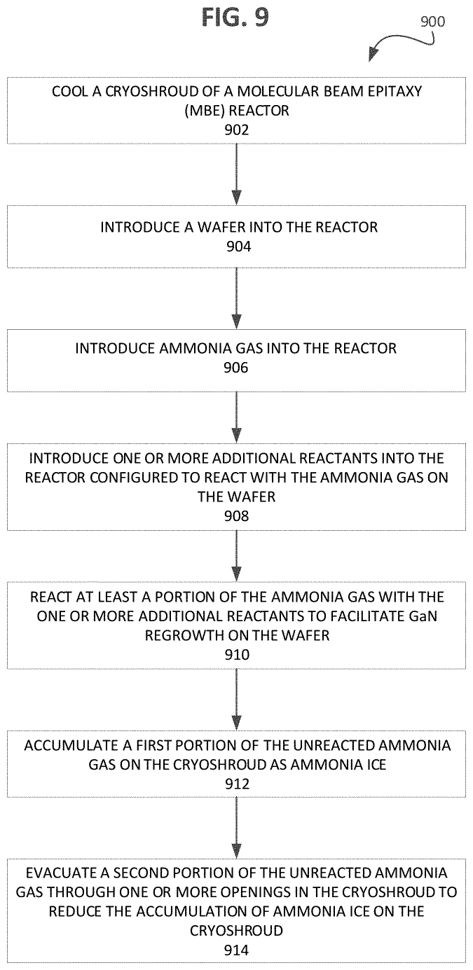

In use, a method 900 for GaN regrowth using ammonia gas as a nitrogen source with reduced formation of ammonia ice is illustrated in FIG. 9. In one or more embodiments, method 900 is used for the unit process of n+GaN contact regrowth using ammonia as a nitrogen source. Method 900 is illustrated as a set of operations or blocks 902 through 914 and is described with continuing reference to FIGS. 3 and 8. One or more blocks that are not expressly illustrated in FIG. 9 may be included before, after, in between, or as part of the blocks 902 through 914. In one or more embodiments, the blocks 902 through 914 are performed by an MBE reactor system, such as system 800 in FIG. 8, using a reactor in accordance with the embodiments described herein with respect to FIGS. 2-7B. In some embodiments, the method 900 may take between about 30 to 40 minutes to complete. For instance, in some embodiments, the method 900 may take 30, 31, 32, 33, 34, 35, 36, 37, 38, 39, or 40 minutes to complete.

At step 902, a cryoshroud of an MBE reactor is cooled. In one or more embodiments, the cryoshroud may be cooled using liquid nitrogen. In some embodiments, the cryoshroud may include one or more cryopanels having tubes connected to a cooling source, such as a liquid nitrogen source, and the cryoshroud may be cooled by pumping liquid nitrogen through tubes in the cryoshroud.

At step 904, a wafer is introduced into the reactor. In one or more embodiments, the wafer may be introduced into the reactor by a wafer introducing means, such as wafer introducing means 806 in FIG. 8, through the wafer port. In some embodiments, the wafer is further introduced through one or more openings in the cryoshroud, such as gap 318 in FIG. 3; in other embodiments, the wafer is introduced above the cryoshroud; in other embodiments, the wafer is introduced below the cryoshroud. In some embodiments, the wafer is accepted by a wafer platform, such as wafer platform 314 coupled to shaft 312 in FIG. 3. In some embodiments, the wafer is positioned on the wafer platform for GaN regrowth.

At step 906, ammonia gas is introduced into the reactor. The ammonia gas is used as a nitrogen source for regrowth of GaN in accordance with the embodiments of the invention. In contrast, most conventional nitride-based material growth processes use plasma as a nitrogen source. Gas injectors, such as injectors 310 in FIG. 3, may be used to introduce ammonia gas in step 906. Specifically, a hydride source gas injector may be used to introduce the ammonia gas. The introduced ammonia gas flows from the gas injectors towards the surface of the wafer as a result of the gas injectors being angled towards the wafer in some embodiments.

At step 908, one or more additional reactants are introduced into the reactor. These reactants are introduced to react with the ammonia gas on the surface of the wafer. Gas injectors, such as injectors 310 in FIG. 3, may be used to introduce the reactants in step 908. In one or more embodiments, at least one of the gas injectors comprises a hydride source and at least one of the gas injectors comprises a gallium source. In some embodiments, one or more additional reactants introduced into the reactor is a hydride introduced using a hydride source gas injector. A hydride may be used as a dopant for the GaN regrowth. Non-limiting examples of reactants that may be introduced into the reactor as hydrides include NH₃, SiH₄, Si₂H₆, GeH₄, and any combination thereof. In some embodiments, one or more additional reactants introduced into the reactor is a source of gallium in the GaN regrowth introduced using a gallium source injector. Non-limiting examples of gallium sources include TEGa, TMGa, GaCl₃, and any combination thereof. In some embodiments, the introduced reactants flow from the gas injectors towards the surface of the wafer as a result of the gas injectors being angled towards the wafer.

At step 910, at least a portion of the ammonia gas reacts with the one or more additional reactants to facilitate GaN regrowth on the wafer. The ammonia gas and the one or more additional reactants introduced into the reactor at steps 904 and 906 flow directly to the surface of the wafer and react to facilitate GaN regrowth. The use of ammonia gas as the nitrogen source in GaN regrowth allows for more selective growth on the wafer. That is, ammonia gas as a nitrogen source allows for more control over where growth occurs on the wafer. At least a portion of the ammonia gas and at least a portion of the additional reactants do not react, making up excess material that must be pumped from the reactor in order to maintain the pressure. Continuous injection of ammonia gas, one or more additional reactants, or both will cause pressure to build up in the reactor. To prevent pressure build-up (i.e., to maintain an appropriate pressure) the excess unreacted material is pumped out of the reactor.

At step 912, a first portion of the unreacted ammonia gas accumulates on the cryoshroud as ammonia ice. After step 910, some of the unreacted ammonia gas accumulates on the cryoshroud as ammonia ice as a result of the cryoshroud being cooled in step 902. In some embodiments, at least a portion of the unreacted one or more additional reactants may accumulate within the ammonia ice on the cryoshroud.

At step 914, a second portion of the unreacted ammonia gas is evacuated through one or more openings in the cryoshroud. The evacuation of unreacted ammonia gas through the openings in the cryoshroud facilitates reduced accumulation of ammonia ice on the cryoshroud. Whereas a traditional MBE reactor does not include additional gaps or openings for enhanced evacuation of ammonia, MBE reactors and systems in accordance with embodiments of the present invention include one or more openings through which a portion of the ammonia gas escapes the reactor. As a result, a reduced amount of ammonia ice is formed on the cryoshroud because the unreacted portions of ammonia that would otherwise condense on the cryoshroud in conventional MBE reactors may evacuate the reactor through the gaps or openings. Further, a reduced amount of unreacted additional reactants (i.e., contaminants) are trapped within the ammonia ice on the cryoshroud, which provides additional benefits as described herein.

One or more pumps as described herein are used to pump unreacted portions of ammonia gas out of the reactor through the gaps or openings in the cryoshroud. In one or more embodiments, the evacuation in step 914 includes high throughput vacuum pumping. The pumping speed and efficiency in a conventional MBE reactor remains limited due to its design. In contrast, MBE reactors in accordance with embodiments of the present invention improve the pumping efficiency of an MBE reactor. This is accomplished, in part, by the gaps or openings formed in the cryoshroud through which unreacted ammonia gas may escape during GaN regrowth.

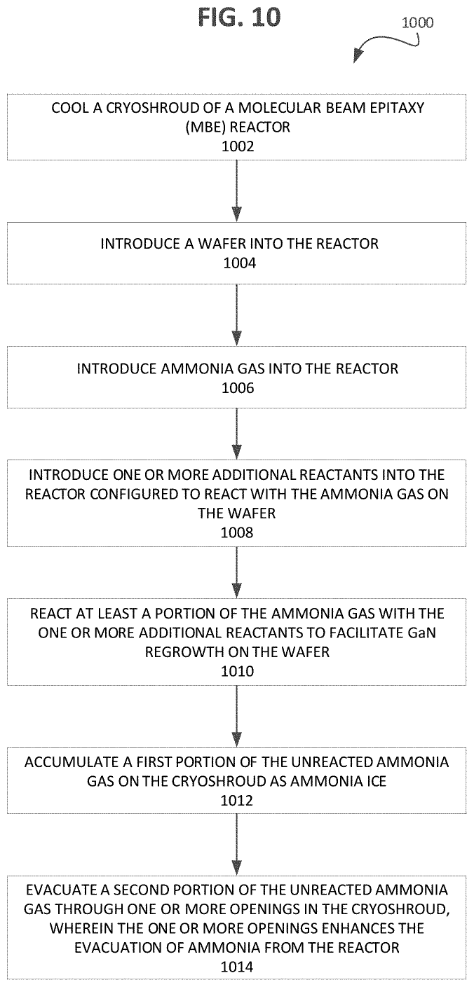

Another non-limiting example of a method for GaN regrowth using ammonia gas as a nitrogen source with enhanced evacuation of ammonia is illustrated in FIG. 10. As shown in FIG. 10, method 1000 is similar to the method 900 in FIG. 9, but step 1014 in method 1000 provides an improvement of enhanced evacuation of ammonia from the reactor as described herein.

Regeneration of MBE Reactor.

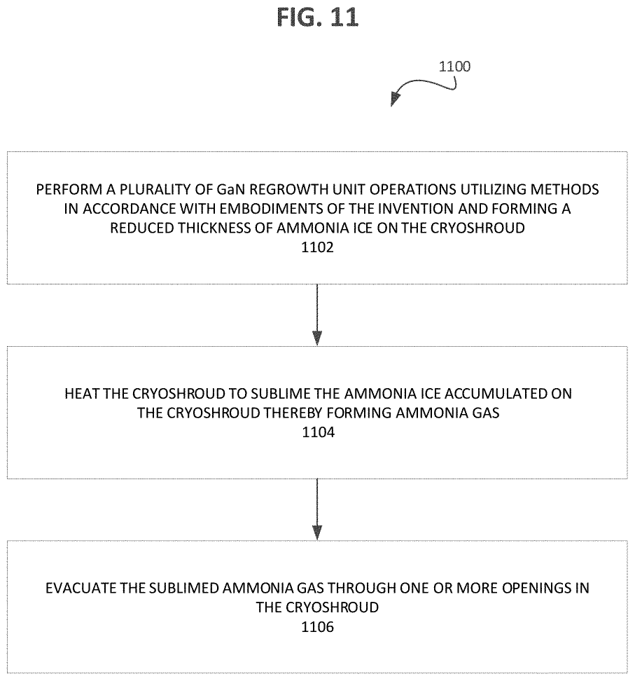

One non-limiting example of a method for improving the turnover time of an MBE reactor after a GaN regrowth process using ammonia as a nitrogen source is illustrated in FIG. 11. In use, method 1100 involves heating a cryoshroud in a reactor after one or more GaN regrowth unit operations to facilitate melting and removal of condensed ammonia ice from the cryoshroud. This process may be referred to as regeneration. Method 1100 is illustrated as a set of operations or blocks 1102 through 1106, and is described with continuing reference to FIGS. 3, 8, and 9. One or more blocks that are not expressly illustrated in FIG. 11 may be included before, after, in between, or as part of the blocks 1102 through 1106. In one or more embodiments, the blocks 1102 through 1106 are performed by an MBE reactor system, such as system 800 in FIG. 8, using a reactor as described by the embodiments herein with respect to FIGS. 2-7B.

At step 1102, a plurality of GaN regrowth unit operations are performed according to the method 900 as described herein with respect to FIG. 9. Compared to the ammonia ice accumulated during conventional methods using conventional MBE reactors, method 900 forms a reduced thickness of ammonia ice on the cryoshroud. In some embodiments, the number of unit operations performed before proceeding to step 1104 to begin regeneration of the cryoshroud ranges from 10 to 20 unit operations. For example, in some embodiments, the number of unit operations performed may be 10, 11, 12, 13, 14, 15, 16, 17, 18, 19, or 20 unit operations. Typically, in use according to the embodiments described herein, 12 unit operations are performed prior to regeneration of the reactor.

At step 1104, the cryoshroud is heated to sublime the ammonia ice accumulated on the cryoshroud thereby forming ammonia gas. Step 1104 is the first step in the regeneration process to melt and remove the ammonia ice and prepare the reactor for maintenance or further GaN regrowth unit operations. In one or more embodiments, prior to step 1104, the wafer with GaN regrowth may be removed from the reactor using wafer introducing means. After the wafer is removed from the reactor, one or more gases may be injected into the cryoshroud to warm the cryoshroud. During step 1104, the ammonia ice accumulated on the cryoshroud sublimes, transforming directly into ammonia gas. In some embodiments, the one or more additional reactants (i.e., contaminants) trapped within the ammonia ice are released from the ammonia ice. Some of these reactants may be evacuated along with the sublimed ammonia gas in step 1106. Some of these reactants may fall towards the bottom of the reactor. As discussed herein, the reduced formation of ammonia ice on the cryoshroud also reduces the amount of unreacted additional reactants trapped within the ammonia ice. As a result, fewer reactants may fall towards the bottom of the reactor as compared to conventional MBE reactors and methods, thereby reducing the risk of contamination or damage to the gas injectors or other components of the MBE reactor during regeneration.

At step 1106, the sublimed ammonia gas is evacuated through one or more openings in the cryoshroud. One or more pumps as described herein are used to pump sublimed ammonia gas out of the reactor through the gaps or openings in the cryoshroud. In one or more embodiments, the evacuation in step 1106 includes high throughput vacuum pumping. The pumping speed and efficiency in a conventional MBE reactor remains limited due to its design. In contrast, MBE reactors in accordance with embodiments of the present invention improve the pumping efficiency of an MBE reactor. This is accomplished, in part, by the gaps or openings formed in the cryoshroud through which sublimed ammonia gas may escape during a regeneration process. Increased pumping efficiency of the MBE reactor during regeneration improves the time required to evacuate the sublimed ammonia gas, thereby improving turnover time of the MBE reactor.

The time required to heat the cryoshroud, sublime the accumulated ammonia ice, and evacuate the sublimed ammonia gas may be referred to as the turnover time, or the time for regeneration of the reactor. The turnover time of method 1100 is reduced, as compared to that of a conventional MBE reactor, as a result of the reduced thickness of ammonia ice formed on the cryoshroud at step 1102. The turnover time of method 1100 is an improvement over conventional methods because less ammonia ice is condensed on the cryoshroud as a result of embodiments of the improved reactor design described herein. Specifically, less ice is accumulated on the cryoshroud because gaps or openings formed in the cryoshroud in accordance with the embodiments described herein provide enhanced evacuation of unreacted ammonia gas that would otherwise condense on the cryoshroud. In some embodiments, the improved turnover time for the MBE reactor ranges from 4 to 24 hours. For example, the turnover time may be 4, 5, 6, 7, 8, 9, 10, 11, 12, 13, 14, 15, 16, 17, 18, 19, 20, 21, 22, 23, or 24 hours. In other embodiments, the improved turnover time for the MBE reactor is less than 4 hours. For example, the turnover time may be 1, 2, or 3 hours. In use, the typical turnover time for the structures and systems described herein is about 4 hours. In contrast, the turnover time for a conventional MBE reactor is greater than 24 hours.

Whereas a traditional MBE reactor is only taken offline for maintenance infrequently due to the long downtime to fully melt the condensed ammonia ice, MBE reactors in accordance with embodiments of the present invention may be taken offline more frequently due to the reduced thickness of the ammonia ice condensed on the cryoshroud. In some embodiments, the number of unit operations performed before performing steps 1104 and 1106 ranges from 10 to 20 unit operations. For example, in some embodiments, the number of unit operations performed may be 10, 11, 12, 13, 14, 15, 16, 17, 18, 19, or 20 unit operations. Typically, in use according to the embodiments described herein, 12 unit operations are performed prior to regeneration of the reactor.

A further benefit of the improvements in the turnover time of an MBE reactor after a GaN regrowth process according to embodiments of the invention is an improvement in the manufacturing efficiency of highly scaled, high-frequency gallium nitride (GaN) high electron mobility transistor (HEMT) devices. In some embodiments, the methods described herein are used in the manufacturing of HEMT devices. As such, improvements in the efficiencies of the methods described herein provide further improvement in the efficiencies of the manufacturing processes utilizing these methods.

While preferred embodiments of the present invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention. It is intended that the following claims define the scope of the invention and that methods and structures within the scope of these claims and their equivalents be covered thereby.

1-85. (canceled)

86. A molecular beam epitaxy (MBE) reactor for GaN regrowth using ammonia as a nitrogen source, the reactor comprising:
a chamber;
a wafer port through which a wafer is introduced into the chamber;
one or more pump ports;
a cryoshroud positioned within the chamber, the cryoshroud comprising an upper component and a lower component, wherein the lower component is spaced from the upper component by a fixed distance and wherein the spacing of the upper and lower components enhances evacuation of ammonia from the reactor; and
a plurality of gas injectors configured to introduce reactants into the chamber.

87. The reactor of claim 86, wherein the cryoshroud comprises one or more liquid nitrogen-filled cryopanels.

88. The reactor of claim 86, wherein the height of the upper component of the cryoshroud is greater than the height of the lower component of the cryoshroud.

89. The reactor of claim 86, wherein the height of the upper component of the cryoshroud is less than the height of the lower component of the cryoshroud.

90. The reactor of claim 86, wherein the wafer port, the one or more pump ports, or any combination thereof are centered between the upper and lower components of the cryoshroud.

91. The reactor of claim 86, wherein the wafer port, the one or more pump ports, or any combination thereof are not centered between the upper and lower components of the cryoshroud.

92. The reactor of claim 86, wherein the upper component, the lower component, or both at least partially overlap the wafer port, the one or more pump ports, or any combination thereof.

93. The reactor of claim 86, wherein the distance between the upper component and the lower component ranges from 2 inches to 8 inches.

94. The reactor of claim 86, wherein the distance from the bottom edge of the lower component to the top edge of the upper component is less than the height of the chamber.

95. The reactor of claim 86, wherein the plurality of gas injectors enter through a bottom surface of the chamber.

96. The reactor of claim 86, wherein the plurality of gas injectors are angled towards the wafer.

97. The reactor of claim 86, wherein at least one of the plurality of gas injectors comprises a distal end, and wherein the distal end is positioned above a bottom level of the lower component of the cryoshroud.

98. The reactor of claim 86, wherein at least one of the plurality of gas injectors comprises a hydride source and at least one of the plurality of gas injectors comprises a gallium source.

99. The reactor of claim 98, wherein the hydride source is configured to introduce at least one reactant selected from the group consisting of: NH₃, SiH₄, Si₂H₆, GeH₄, and any combination thereof.

100. The reactor of claim 98, wherein the gallium source is configured to introduce at least one reactant selected from the group consisting of: TEGa, TMGa, GaCl₃, and any combination thereof.

101. The reactor of claim 86, wherein at least one of the plurality of gas injectors comprises a distal end, and the reactor further comprises a mechanical shutter configured to cover the distal end of one or more of the gas injectors.

102. A system for GaN regrowth using ammonia as a nitrogen source, the system comprising:
a molecular beam epitaxy (MBE) reactor comprising:
a chamber;
a wafer port through which a wafer is introduced into the chamber;
one or more pump ports;
a cryoshroud positioned within the chamber and configured to enhance evacuation of ammonia; and
a plurality of gas injectors configured to introduce reactants into the chamber;
one or more pumps connected to the chamber via the one or more pump ports; and
a wafer introducing means configured to introduce the wafer into the chamber through the wafer port.

103. The system of claim 102, further comprising a wafer platform coupled to a shaft positioned through a top surface of the chamber, wherein the wafer platform is configured to accept the wafer from the wafer introducing means.

104. A method for GaN regrowth using ammonia gas as a nitrogen source with reduced formation of ammonia ice, the method comprising:
cooling a cryoshroud of a molecular beam epitaxy (MBE) reactor;
introducing a wafer into the reactor;
introducing ammonia gas into the reactor;
introducing one or more additional reactants into the reactor configured to react with the ammonia gas on the wafer;
reacting at least a portion of the ammonia gas with the one or more additional reactants to facilitate GaN regrowth on the wafer;
accumulating a first portion of the unreacted ammonia gas on the cryoshroud as ammonia ice; and
evacuating a second portion of the unreacted ammonia gas through one or more openings in the cryoshroud to reduce the accumulation of ammonia ice on the cryoshroud.

105. The method of claim 104, wherein accumulating the first portion of the unreacted ammonia gas as ammonia ice further comprises accumulating unreacted portions of the one or more additional reactants within the ammonia ice.
